(19) United States
(12) Patent Application Publication
(10) Pub. No.: US 2006/0181949 A1
(43) Pub. Date: Aug. 17, 2006

(54) Operating system-independent memory power management

(76) Inventor: M. Vittal Kini, Aloha, OR (US)

Correspondence Address: INTEL CORPORATION, P.O. BOX 5326, SANTA CLARA, CA, 95056-5326, US

(21) Appl. No.: 11/027,665

(22) Filed: Dec. 31, 2004

(51) Int. Cl. G11C 8/00

(52) U.S. Cl. 365/230.03

(57) ABSTRACT

Embodiments of the present invention can reduce the power consumption of memory systems by powering down unused portions of memory, independent of operating system activity.

### FIELD OF THE INVENTION

The present invention relates to the field of power management. More specifically, the present invention relates to manage memory power, independent of operating system activity.

### BACKGROUND

In many computer systems, the memory elements can consume a relatively large amount of power. For example, it is not unusual for memory to represent 20-30% of a typical system's total power consumption. For large server systems, the percentage of total power consumed by memory can be even higher. Power consumption can be an important consideration. For example, in mobile devices, such as notebook computers, personal data assistants, cellular phones, etc., power consumption directly affects battery life. In stationary devices, such as desk top computers, servers, routers, etc., the amount of power that they consume can be expensive.

### BRIEF DESCRIPTION OF DRAWINGS

Examples of the present invention are illustrated in the accompanying drawings. The accompanying drawings, however, do not limit the scope of the present invention. Similar references in the drawings indicate similar elements.

FIG. 1 illustrates an example of a computing system without operating system-independent memory power management.

FIG. 2 illustrates an example of a computing system with operating system-independent memory power management according to one embodiment of the present invention.

FIG. 3 illustrates an example of a computing system with multiple operating systems according to one embodiment of the present invention.

FIGS. 4A through 4D illustrate an example of data items in memory locations at four instants in time according to one embodiment of the present invention.

FIG. 5 illustrates a functional block diagram according to one embodiment of the present invention.

FIG. 6 illustrates one embodiment of a method for relocating data items.

FIG. 7 illustrates one embodiment of a method for tracking locations of data items.

FIG. 8 illustrates one embodiment of a method for tracking a new data item.

FIG. 9 illustrates one embodiment of a method for tracking a deleted data item.

FIG. 10 illustrates one embodiment of a method for tracking a relocated data item.

FIG. 11 illustrates one embodiment of a method for setting power states of memory elements.

FIG. 12 illustrates one embodiment of a hardware system that can perform various functions of the present invention.

FIG. 13 illustrates one embodiment of a machine readable medium to store instructions that can implement various functions of the present invention.

### DETAILED DESCRIPTION OF THE INVENTION

In the following description, numerous specific details are set forth in order to provide a thorough understanding of the present invention. However, those skilled in the art will understand that the present invention may be practiced without these specific details, that the present invention is not limited to the depicted embodiments, and that the present invention may be practiced in a variety of alternative embodiments. In other instances, well known methods, procedures, components, and circuits have not been described in detail.

Parts of the description will be presented using terminology commonly employed by those skilled in the art to convey the substance of their work to others skilled in the art. Also, parts of the description will be presented in terms of operations performed through the execution of programming instructions. It is well understood by those skilled in the art that these operations often take the form of electrical, magnetic, or optical signals capable of being stored, transferred, combined, and otherwise manipulated through, for instance, electrical components.

Various operations will be described as multiple discrete steps performed in turn in a manner that is helpful for understanding the present invention. However, the order of description should not be construed as to imply that these operations are necessarily performed in the order they are presented, nor even order dependent. Lastly, repeated usage of the phrase “in one embodiment” does not necessarily refer to the same embodiment, although it may.

Embodiments of the present invention can reduce the power consumption of memory systems by powering down unused portions of memory, independent of operating system activity.

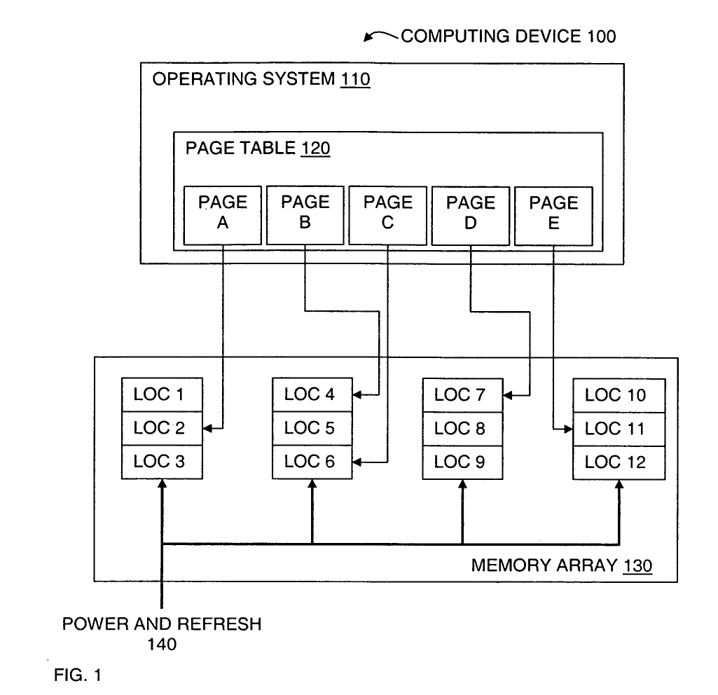

FIG. 1 illustrates an example of a typical computing device 100 without the advantages afforded by embodiments of the present invention. Computer device 100 includes an operating system (OS) 110 and a physical memory array 130. Memory array 130 can provide random access memory (RAM) for OS 110. That is, OS 110 can view array 130 as a set of memory locations that are all continuously and equally available to the OS for storing data, and the OS may write data to, or read data from, any of the memory locations at virtually any time.

OS 110 can maintain a page table 120 to keep track of where pages of data are stored in memory array 130. Page table 120 can track the locations by recording the physical addresses of each page of data in memory array 130. For example, this is illustrated in FIG. 1 by the arrows pointing from pages A, B, C, D, and E in page table 120 to various corresponding locations in memory array 130. In practice, a page table may track many thousands of pages in a memory array at any given time. Pages of data may be continually added and removed from the table and memory array as, for instance, applications close and new applications launch. Servers, in particular, often swap out huge amounts of data in rapid succession.

Most random access memory technologies tend to be dynamic. In dynamic random access memory (DRAM), data decay rapidly and will only be retained so long as operating power is maintained and the data are periodically refreshed. In which case, in order to make the entire array 130 fully available to OS 110 for random access, the entire array 130 is typically fully powered and rapidly refreshed whenever the operating system is active, even if little or no data is being stored. For example, the illustrated embodiment includes power and refresh lines 140 that can uniformly supply the entire memory array 130.

In contrast to this typical computing system, embodiments of the present invention can insert a layer of abstraction between the operating system and the memory resources. With this layer of abstraction, embodiments of the present invention can pack data into a portion of available memory so that another portion of memory can be placed in a lower power state, all the while providing the appearance of a fully operational memory array to an operating system.

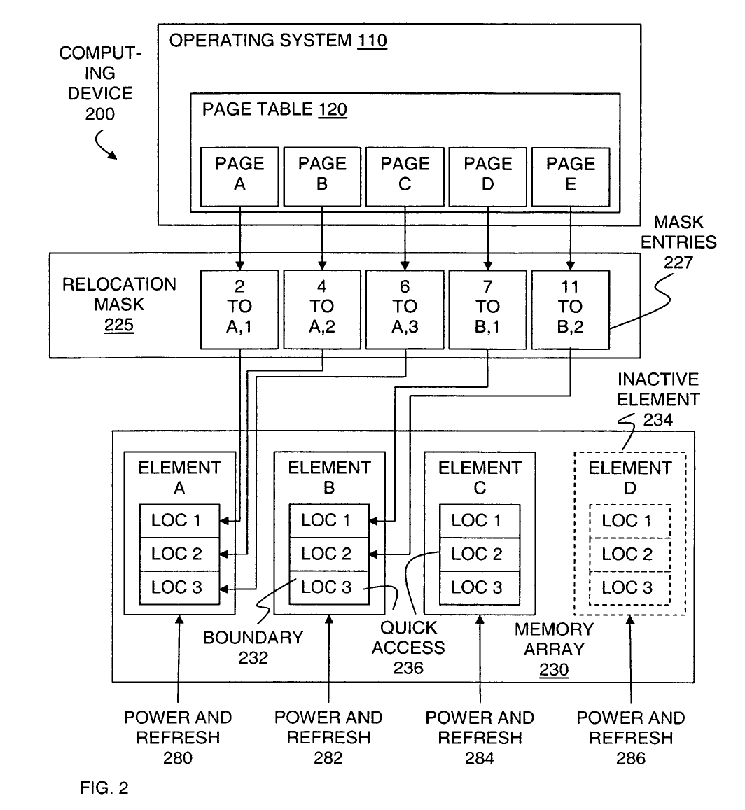

For example, FIG. 2 illustrates a computing device 200 that includes memory power management features according to one embodiment of the present invention. Computing device 200 can include the same operating system (OS) 110 and page table 120 as computing device 100 in FIG. 1. However, in the embodiment of FIG. 2, a relocation mask 225 can provide a layer of abstraction between the OS and memory array 230. Memory array 230 can be partitioned into elements A, B, C, and D, and the memory elements can be individually powered and/or refreshed by lines 280, 282, 284, and 286.

Relocation mask 225 can include a number of entries 227 that can track the locations of data pages as defined by OS 110 in page table 120 to the actual locations of the data pages in the physical memory array 230. For example, as in FIG. 1, page table 120 defines page A to be at location 2 in the memory array. Relocation mask 225, however, maps location 2 to element A, location 1 in memory array 230. Similarly, page B is defined to be at location 4, which is mapped to element A, location 2; page C is defined to be at location 6, which is mapped to element A, location 3; page D is defined to be at location 7, which is mapped to element B, location 1; and page E is defined to be at location 11, which is mapped to element B, location 2.

With the data pages packed into the lower end of memory array 230 as shown, the boundary 232 of packed data is at element B, location 3, and memory elements C and D are empty of data items. Since each memory element in array 230 can be individually powered and refreshed, elements C and D can be set to a lower, inactive power state to save power. For example, the refresh rate could be reduced or stopped entirely, and/or the power level could be reduced or turned off entirely.

However, since OS 110 may write additional data to memory at any time, and since returning an inactive memory element to an active power state may introduce an undesirable delay, the illustrated embodiment can keep a some empty memory active in order to provide quick access memory 236 for OS 110. Any of a variety of techniques can be used to anticipate how much memory is likely to be needed at any given time. For example, statistical algorithms such as those used to pre-fetch data into cache memory for a processor could similarly be used to anticipate how much memory an OS is likely to need given a certain state of a computing device as defined, for example, by the number and type of active applications and/or processes over a period of time. In the illustrated embodiment, empty memory element C can be left active for quick access memory 236 and memory element D may be the only inactive memory element 234. If more memory is needed than anticipated, memory element D can be reactivated. On the other hand, if the computing system were to enter a stand-by mode, with little or no memory activity, then quick access memory may not be needed and both memory elements C and D might be powered down.

To OS 110, the entire memory array 230 can appear fully and continually active whenever the OS is active. OS 110 can define any memory location within array 230 to write, read, or delete data, and mask 225 can direct each memory access to the corresponding physical memory locations. New data can be directed to the quick access memory locations 236 or to holes in the packed end of array 230 left by deleted data. The boundary 232 between packed locations and empty locations can move as data is swapped in and out of array 230. The amount of quick access memory 236 and the number of inactive memory elements 234 can change as the boundary 232 moves and the anticipated memory requirements of the device 200 change.

The data items tracked by page table 120 can take any of a variety of forms. In one embodiment, each data item includes four kilobytes of data. In other embodiments, each data item could be as little as a single bit of data, or up to several kilobytes and beyond. In various other embodiments, the data items could each be a different size.

The pages of data tracked in page table 120 can also come from a variety of different sources and be used in a variety of different ways. For example, the OS itself may generate and use data tracked in page table 120. The data could also belong to any of a variety of applications or processes running on the computing device 200. In another example, the data could comprise paged virtual memory.

Memory array 230 can be configured in a variety of different ways. For example, in one embodiment, memory array 230 may represent a single integrated circuit (IC) chip, or one region within a larger IC chip. In another embodiment, each element A, B, C, and D may represent a separate IC chip coupled to one more printed circuit boards (PCBs), or separate regions dispersed within one or more larger IC chips. Any of a variety memory technologies can be used for memory array 130.

Alternate embodiments may include more or fewer memory elements with individually controlled power states, and each memory element may include more or fewer memory locations. For example, each memory element could include a different number of memory locations. In another example, each memory location could comprise a separate memory element have individually controlled power states.

Power states can be controlled in a variety of different ways. For example, many memory technologies include two refresh mechanisms, an external refresh and a self-refresh. The refresh rate for an external refresh is usually higher and generally consumes more energy. External refresh is often designed to provide faster memory performance when, for instance, a computing device is in an active state. The refresh rate for a self-refresh is usually much slower and generally consumes less energy. Self-refresh is often designed to be the slowest possible refresh that will safely maintain data in memory when, for instance, computing activity is suspended for a prolonged period. In which case, in one embodiment of the present invention, rather than individually controlling both power and refresh for each memory element, all the memory elements may share a common power supply, but be individually controllable to switch between an external refresh and a self-refresh.

In other embodiments, multiple power states could be used simultaneously or selectively. For example, some memory elements could be fully powered down, some could receive power but no refreshes, some could receive power and self-refreshes, and others could be fully active with both power and external refreshes. In another example, when in a stand-by mode of operation, even occupied memory locations may be placed in a reduced power state with, for instance, a lowered power supply and/or self-refreshes. At the same time, the empty memory locations could be placed in even lower power states with, for instance, no power supply and no refreshes. Other embodiments may use any combination of these and other power states.

Embodiments of the present invention be used in virtually any electronic device that includes an operating system and memory. For example, embodiments of the present invention can be used in notebook computers, desk top computers, server computers, personal data assistants (PDAs), cellular phones, gaming devices, global positioning system (GPS) units, and the like.

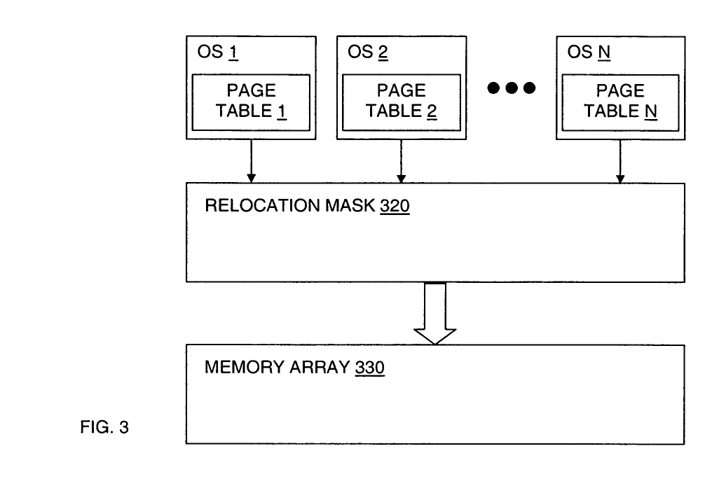

Furthermore, embodiments of the present invention can support multiple operating systems simultaneously. For example, as shown in FIG. 3, operating systems 1 to N can maintain page tables 1 to N. Relocation mask 320 can track the positions of data pages as defined by the N operating systems to physical locations in memory array 330. As with the embodiment of FIG. 2, the data can be packed into elements within memory array 330 (not shown), and empty memory elements within array 330 can individually enter lower power states.

Managing memory power can itself consume a certain amount of power. In particularly active computing systems, there may be a point at which managing memory power consumes more power than it saves. For example, if the memory is re-packed every time a new data item is written or deleted, and large amounts of data are frequently swapped in and out of memory with very little memory left unused, there may be a net increase in power consumption due to managing memory power. In which case, rather than continually performing the various power management functions, it may be beneficial to perform some of the functions on a periodic basis, or to discontinue some or all of the functions entirely, especially during heavy memory traffic.

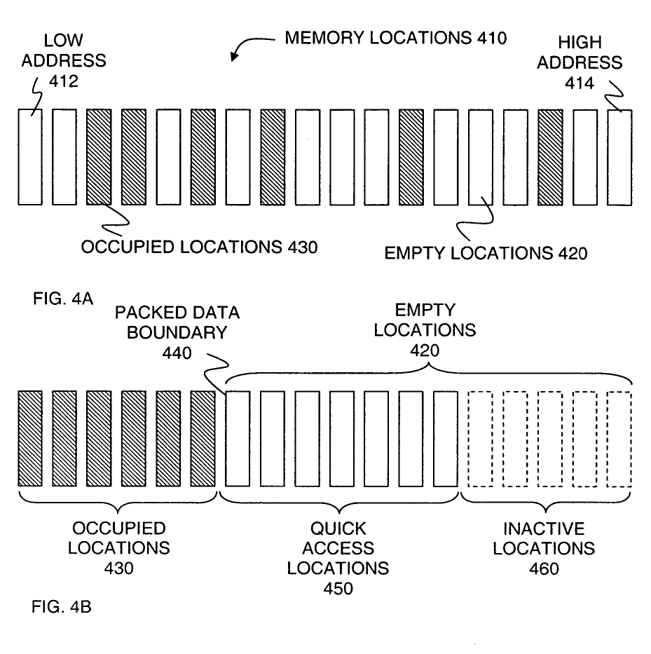

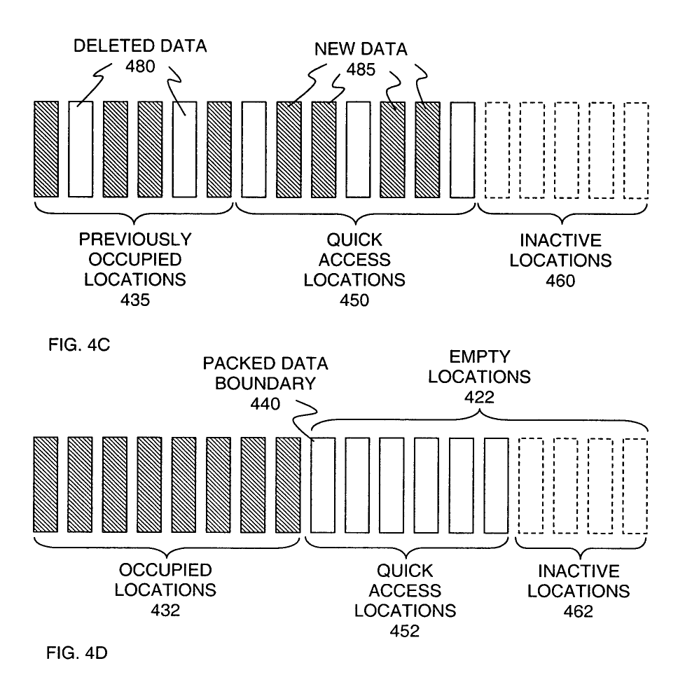

FIGS. 4A through 4D illustrate an example of activating, and periodically performing, various functions of memory power management according to one embodiment of the present invention. FIG. 4A illustrates a number of memory locations 410 that can each be individually controlled to enter a lower power state. At the instant in time show in FIG. 4A however, all of the memory elements 410 are in an active state. For instance, locations 410 may all be initially active when a machine turns on, or memory power management may have been previously discontinued.

In certain embodiments, a user may have an option to manually disable or enable memory power management. In other embodiments, memory power management may automatically activate or deactivate upon the occurrence of some event, such as a notebook computer switching from AC power to battery power, the power level of a battery dwindling to a certain level, or the data traffic and free memory space reaching certain limits.

In any event, since all of the memory elements 410 are active in FIG. 4A, data can be written to any location. For example, a relocation mask may simply write the data to whatever locations the operating system defines. In the illustrated embodiment, there are six occupied locations 430 and twelve empty locations 420. The occupied locations 430 are shaded to represent stored data, and are dispersed in apparently random fashion between the low address memory location 412 and the high address memory location 414.

FIG. 4B illustrates the memory locations 410 after memory power management has been activated. In the illustrated embodiment, the data from the occupied locations 430 have been relocated to pack the data into lower address locations. The boundary 440 for the packed data separates the occupied locations 430 from the empty locations 420.

In other embodiments, the data items could be packed in various other ways. For example, the data items could be packed into higher address locations, or the data items could start packing at a certain address and fill each address location up and/or down from that address. In this last situation, the boundary separating the packed locations from the empty locations could include two addresses, one at the low end and one at the high end of the packed data. In yet another example, data could be packed into segments of address locations, with empty address locations interspersed between pairs of packed segments. In this situation, the boundary separating the packed and empty locations could include many address locations, at the low and high ends of each packed segment.

Referring again to FIG. 4B, the illustrated embodiment shows seven memory locations 450 that can be left active for quick access. For instance, given the current state of the computing device in which the memory locations are being used, seven memory locations may be anticipated to meet the memory needs of the device. The remaining five memory locations 460 can be placed in an inactive state to save power.

Between FIGS. 4B and 4C, data has been deleted from two memory locations 480 among the previously occupied locations 435, and new data has been written to four memory locations 485 among the quick access locations 450. Other than recording what data has been deleted and directing new data to the quick access locations, memory power management may have done little else since FIG. 4B. With this low level of active, memory power management may consume very little power. Meanwhile, the same five memory locations 460 can remain inactive, potentially resulting in a significant net power savings.

Between FIG. 4C and FIG. 4D, another iteration of packing and power state setting has occurred. This iteration may have been triggered by any number of events. For example, it may simply have been time for a periodic iteration, or the number of empty quick access locations may have dropped to a certain level, or the anticipated amount of quick access memory may have changed. Whatever the cause, the lower address locations 432 have been re-packed with the data from the eight occupied memory locations, the number of quick access locations 452 has dropped from seven to five, and the number of inactive locations 462 has dropped from five to four. Similar iterations of packing and power state setting may occur each time a trigger event occurs.

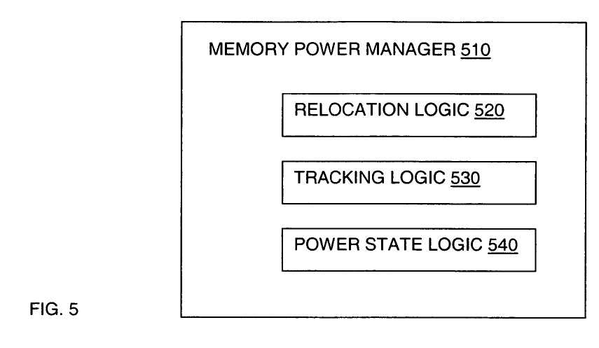

FIG. 5 illustrates a functional block diagram of a memory power manager 510 that can implement various embodiments of the present invention, such as those described above. Relocation logic 520 can pack data into portions of memory. Tracking logic 530 can manage the relocation mask to direct and track memory accesses to active memory locations. Power state logic 540 can anticipate the quick access memory needs for a computing system and reduce the power state of any remaining, empty memory locations. These three basic functions can be implemented in any number of different ways, including hardware, software, firmware, or any combination thereof.

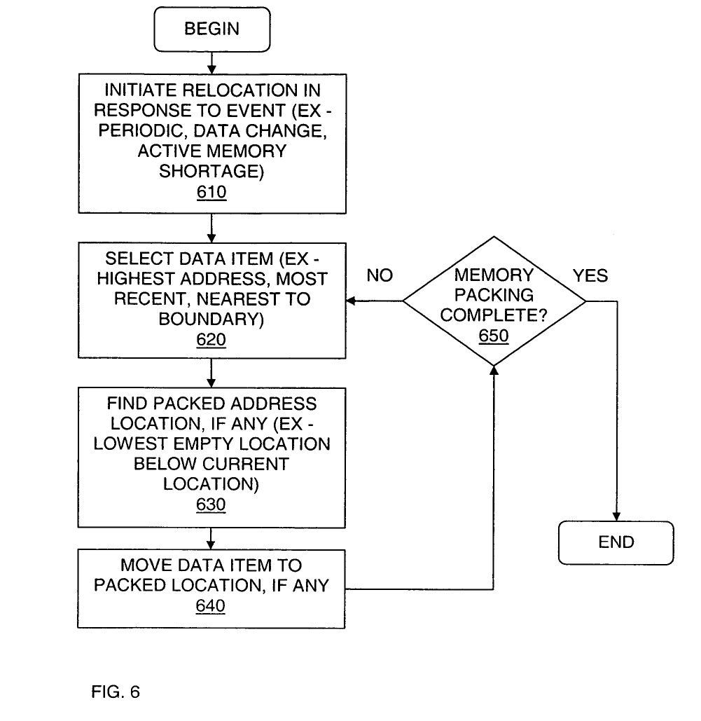

FIGS. 6 through 11 illustrate some examples of methods that can be performed by memory power manage 510 according to various embodiments of the present invention.

FIG. 6 illustrates one embodiment of a method for relocating data items in a memory array. At 610, the method can initiate a relocation in response to a triggering event. For example, a relocation may be triggered periodically, each time data is written or deleted from the memory array, when there is a shortage of active memory, etc.

At 620, the method can select a data item to be relocated. Any number of criteria can be used to decide which data item to select. For example, the method may start at a high address end of the memory array, or the active memory elements in the memory array, and scan down until a data item is encountered. In another example, when a relocation is initiated in response to a new data item being written to memory, the method may simply select the most recently written data item. In yet another example, the method may start at a previously defined boundary between packed data and empty memory locations and scan up until a data item is encountered.

At 630, the method can look for a packed address location for the data item. A packed address location may be an empty location closer to some target location than the current location of the selected data item. For example, when packing data items to the low end of the memory array, the target location is likely to be the lowest address location. In which case, the method may start at the lowest address location and scan up to the first empty location. If the first empty location is lower than the current location of the selected data item, then the empty location may be a good place to pack the selected data item. By selecting a data item starting from a highest address location in 620 and looking for a packed address location starting from a lowest address location in 630, the method can fill in empty locations in the low end of the memory array with data items from the high end.

The method may not find a packed address location for the selected data item. For example, if the selected data item happens to be written to the first memory location in the quick access memory at the boundary between the packed data and the empty memory locations, the selected data item may already packed. As another example, if a previously packed data item is deleted from a memory location and the selected data item happens to be written to the same memory location, the selected data item may already be packed.

Where all of the data items are the same size, looking for a packed address location may be as simple as finding an empty address location. Where the data items can be different sizes, looking for a packed address location can also include comparing the size of an empty block of data with the size of the selected data item. If an empty block of data is smaller than the selected data item, some embodiments of the present invention may skip over the empty block and look for a larger block. Other embodiments of the present invention may partition the selected data item and fit different partitions into different empty blocks of memory. In which case, a relocation mask may track multiple memory locations for data items. Alternately, a relocation mask may track just a first partition of each data item and each partition may include a pointer to where the next partition is stored in memory. Other embodiments may use any of a wide variety of techniques to fit data items into memory locations and keep track of them.

Referring again to FIG. 6, at 640 the method can move the selected data item into the packed address location, assuming a packed address location was found in 630. If not packed address location was found, the method can leave the data item where it is.

At 650, if the all the data is packed, the method can end. If not, the method can continue to select another data item to try to pack it. Recognizing when packing is complete may depend on how the data is being packed. For example, if data items are being packed from the low end of the memory array, the method can scan up from the low end to the first empty address location. Then, the method can continue to scan to see if any active memory locations higher than the first empty location contain a data item. If all the higher locations are empty, then all the data may be packed.

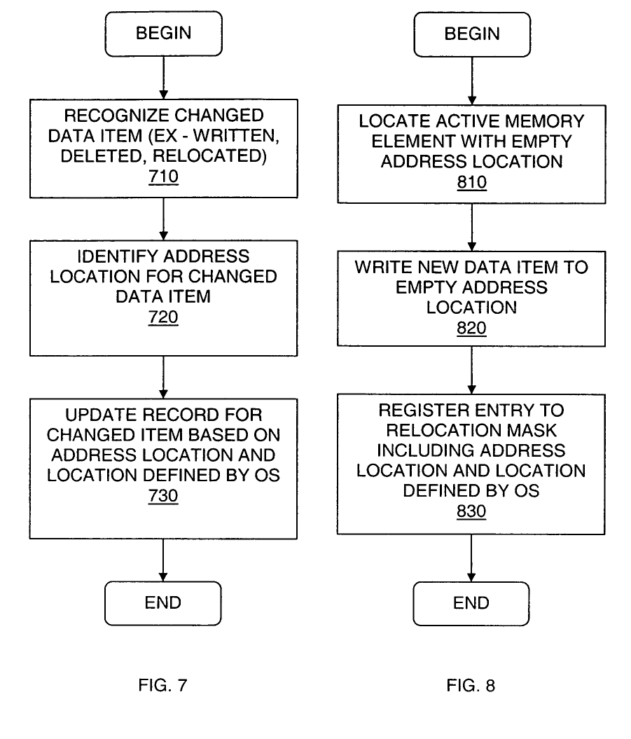

FIG. 7 illustrates one embodiment of a method for tracking data items in a memory array. At 710, the method can recognize a changed data item. For example, the changed data may be a data item to be written to the memory array, a data item deleted from the memory array, or a data item relocated and packed within the memory array. At 720, the method can identify an address location associated with the changed data item and, at 730, the method can update a record for the changed data item in a relocation mask based on the identified address location and a location defined by an operating system. These last two functions can take a variety of different forms depending on the type of changed data item. FIGS. 8 through 10 illustrate a few examples of what these last two functions may entail.

FIG. 8 illustrates one embodiment involving a new data item being written to a memory array. At 810, the method can locate an active memory element with an empty address location using a relocation mask. For example, the method may look first to a section of the memory array that was previously packed for any holes that may have been left by deleted data. Next, the method may look for an available location in quick access memory. If no locations can be found in either of those sections of the memory array, the method may need to reactivate a memory element and select a memory location there.

Once an empty memory location has been located, the method can write the new data item to the empty memory location at 820. Then, at 830, the method can register an entry in a relocation mask for the data item. The entry may include, for instance, an address of the data item in physical memory as well as the location for the data item as defined by an operating system.

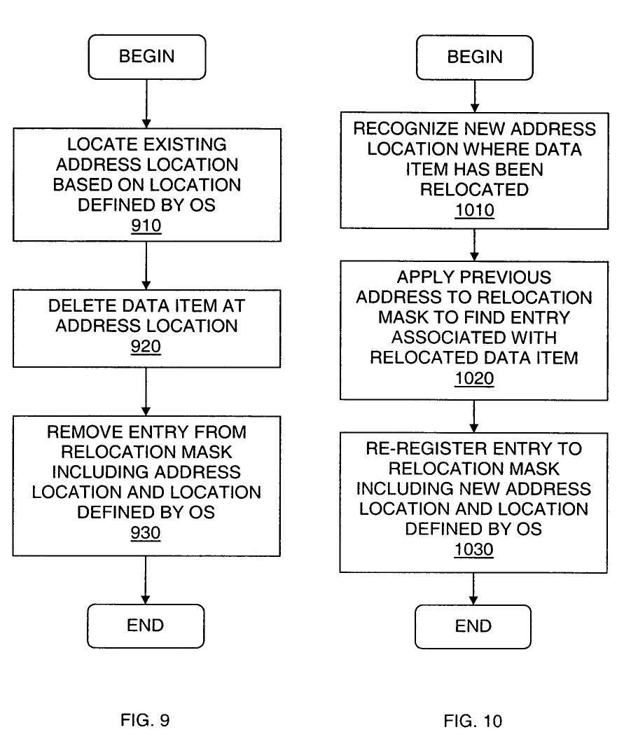

FIG. 9 illustrates one embodiment involving a deleted data item. At 910, the method can locate an existing address location for the data item in a relocation masked based on a location defined by an operation system. For example, an operating system may indicate that a data item should be deleted. The operating system's page table may define a particular address location where the operating system thinks the data item is stored. The data item, however, may have been relocated within the physical memory array. The address provided by the operating system can be used in a relocation mask to find the actual address location in physical memory array.

At 920, the method can delete the data item from the physical memory location, and, at 930, the method can delete the entry for the data item from the relocation mask.

FIG. 10 illustrates one embodiment involving a relocated data item. At 1010, the method can recognize a new address location to which the data item has been relocated. At 1020, the method can apply the previous address location of the data item to a relocation mask to find an entry associated with the relocated data item. Then, at 1030, the method can re-register the entry to the relocation mask, matching the new address location for the data item with the address location defined by an operating system.

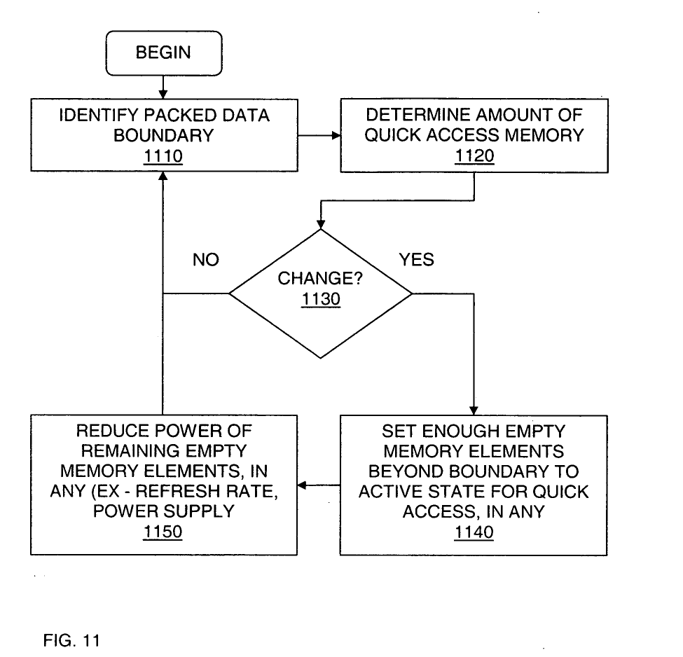

FIG. 11 illustrates one embodiment setting power states for memory elements. At 1110, the method can identify a packed data boundary separating the packed data from empty memory locations. For example, when data is packed to a low end of a memory array, the method can scan up from the low end and identify the boundary at the first empty memory location.

At 1120, the method can determine an amount of quick access memory. For example, any of a variety of statistical algorithms can be used to anticipate what the likely memory needs will be for a computing device. If the computing device is in a state of low activity, like a stand-by mode, then the method may determine that little or no quick access memory is needed. On the other hand, if the computing device is in a state of especially high activity, the method may determine that all available memory should be ready for quick access.

At 1130, the method determines if either the packed data boundary or the amount of quick access memory has changed. For example, if the memory array undergoes an iteration of packing, the position of the boundary may change. Similarly, if the state of the computing device changes due to, for instance, an additional application being launched or a process completing, then the amount of quick access memory that is anticipated to be needed may change. If no change is detected at 1130, the method may loop through 1110 and 1120 many times, monitoring changes.

When and if a change is detected at 1130, the method can set one or more empty memory elements to an active state if any quick access memory is needed at 1140. If no quick access memory is needed, of if a partially packed memory element includes enough empty memory locations to provide the quick access memory, the method may not set any empty memory elements to an active state.

At 1150, the method can set the power state of any remaining, empty memory elements to a reduced power state. For example, the method may reduce the refresh rate, disable the refresh rate, reduce the supply voltage, and/or disable the supply voltage to one or more empty memory elements.

FIGS. 2-11 illustrate a number of implementation specific details. Other embodiments may not include all the illustrated elements, may arrange the elements differently, may combine one or more of the elements, may include additional elements, and the like. Furthermore, the various functions of the present invention can be implemented in any number of ways.

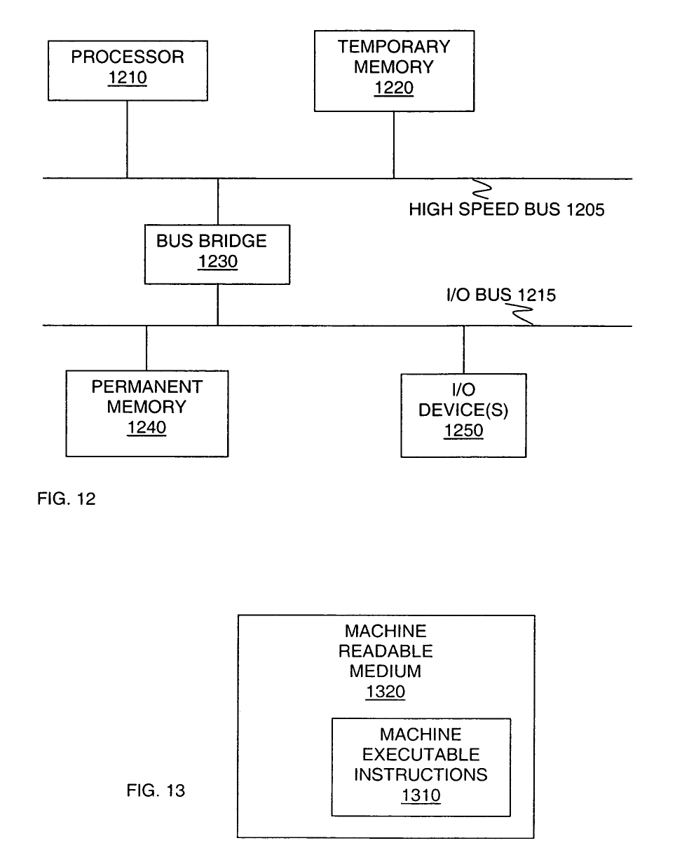

FIG. 12 illustrates one embodiment of a generic hardware system that can bring together the functions of various embodiments of the present invention. In the illustrated embodiment, the hardware system includes processor 1210 coupled to high speed bus 1205, which is coupled to input/output (I/O) bus 1215 through bus bridge 1230. Temporary memory 1220 is coupled to bus 1205. Permanent memory 1240 is coupled to bus 1215. I/O device(s) 1250 is also coupled to bus 1215. I/O device(s) 1250 may include a display device, a keyboard, one or more external network interfaces, etc.

Certain embodiments may include additional components, may not require all of the above components, or may combine one or more components. For instance, temporary memory 1220 may be on-chip with processor 1210. Alternately, permanent memory 1240 may be eliminated and temporary memory 1220 may be replaced with an electrically erasable programmable read only memory (EEPROM), wherein software routines are executed in place from the EEPROM. Some implementations may employ a single bus, to which all of the components are coupled, while other implementations may include one or more additional buses and bus bridges to which various additional components can be coupled. Similarly, a variety of alternate internal networks could be used including, for instance, an internal network based on a high speed system bus with a memory controller hub and an I/O controller hub. Additional components may include additional processors, multiple processor cores within process 1210, a CD ROM drive, additional memories, and other peripheral components known in the art.

Various functions of the present invention, as described above, can be implemented using one or more of these hardware systems. In one embodiment, the functions may be implemented as instructions or routines that can be executed by one or more execution units, such as processor 1210, within the hardware system(s). As shown in FIG. 13, these machine executable instructions 1310 can be stored using any machine readable storage medium 1320, including internal memory, such as memories 1220 and 1240 in FIG. 12, as well as various external or remote memories, such as a hard drive, diskette, CD-ROM, magnetic tape, digital video or versatile disk (DVD), laser disk, Flash memory, a server on a network, etc. In one implementation, these software routines can be written in the C programming language. It is to be appreciated, however, that these routines may be implemented in any of a wide variety of programming languages.

In alternate embodiments, various functions of the present invention may be implemented in discrete hardware or firmware. For example, one or more application specific integrated circuits (ASICs) could be programmed with one or more of the above described functions. In another example, one or more functions of the present invention could be implemented in one or more ASICs on additional circuit boards and the circuit boards could be inserted into the computer(s) described above. In another example, one or more programmable gate arrays (PGAs) could be used to implement one or more functions of the present invention. In yet another example, a combination of hardware and software could be used to implement one or more functions of the present invention.

Thus, operating system-independent memory power manage is described. Whereas many alterations and modifications of the present invention will be comprehended by a person skilled in the art after having read the foregoing description, it is to be understood that the particular embodiments shown and described by way of illustration are in no way intended to be considered limiting. Therefore, references to details of particular embodiments are not intended to limit the scope of the claims.

What is claimed is:

1. A method comprising:
relocating data items among a plurality of memory elements comprising a physical memory array, to pack said data items into particular ones of the plurality of memory elements;
tracking locations of the data items in the physical memory array with respect to corresponding locations of the data items as defined by an operating system; and
reducing a power state of at least one empty memory element among the plurality of memory elements that contains none of the data items.

2. The method of claim 1 further comprising:
tracking locations of the data items in the physical memory array with respect to additional corresponding locations of the data items as defined by at least one additional operating system.

3. The method of claim 1 wherein relocating the data items comprises:
initiating a relocation of the data items in response to an event selected from a group comprising an expiration of a time period, a new data item written to the physical memory array, and an existing data item deleted from the physical memory array.

4. The method of claim 1 wherein relocating the data items comprises:
selecting a particular data item among the plurality of data items;
determining if a packed location is available within the physical memory array for the particular data item; and
moving the particular data item to the packed location if the packed location is available.

5. The method of claim 4 wherein relocating the data items further comprises:
repeating the selecting, determining, and moving until the plurality of data items are packed.

6. The method of claim 4 wherein selecting the particular data item comprises selecting the particular data item from a group comprising a first data item down from a highest address location in the physical memory array, a data item most recently written to the physical memory array, and a first data item beyond an address location defining a packed data boundary.

7. The method of claim 4 wherein determining if a packed location is available comprises:
identifying a first empty address location up from a lowest address location in the physical memory array; and
determining if the first empty address location is lower than an address location of the particular data item.

8. The method of claim 1 wherein tracking the locations of the data items comprises:
recognizing a changed data item in the plurality of data items;
identifying an address location in the physical memory array for the changed data item; and
updating a record for the changed data item based on the address location and the corresponding location of the changed data item as defined by the operating system.

9. The method of claim 8 wherein recognizing the changed data item comprises recognizing the changed data item from a group comprising a data item written to the physical memory array, a data item deleted from the physical memory array, and a data item relocated within the physical memory array.

10. The method of claim 8 wherein identifying the address location in the physical memory array for the changed data item comprises:
locating an active memory element among the plurality of memory elements that has an empty address location; and
writing the changed data item to the empty address location.

11. The method of claim 10 wherein updating the record comprises:
registering an entry to a relocation mask including the empty address location and the corresponding location of the changed data item as defined by the operating system.

12. The method of claim 8 wherein identifying the address location in the physical memory array for the changed data item comprises:
locating an existing address location for the changed data item in the physical memory array based on the corresponding location of the changed data item as defined by the operating system; and
deleting the changed data item from the existing memory location.

13. The method of claim 12 wherein updating the record comprises:
removing an entry from a relocation mask including the existing memory location and the corresponding location of the changed data item as defined by the operating system.

14. The method of claim 8 wherein identifying an address location in the physical memory array for the changed data item comprises:
recognizing a new address location in the physical memory array to which the changed data item has been relocated.

15. The method of claim 14 wherein updating the record comprises:
applying a previous address of the changed data item in the physical memory array to a relocation mask to find an entry associated with the changed data item; and
re-registering the entry to the relocation mask including the new address location and the corresponding location of the changed data item as defined by the operating system.

16. The method of claim 1 wherein reducing the power state comprises an action selected from a group comprising reducing a refresh rate, disabling refreshes, lowering a supply voltage, and disabling a supply voltage.

17. The method of claim 1 wherein reducing the power state comprises:
identifying a packed data boundary among the plurality of memory elements, said packed data boundary to separate the plurality of memory elements into empty memory elements and occupied memory elements;
determining an amount of quick access memory;
setting enough of the empty memory elements to an active power state to supply the amount of quick access memory; and
reducing the power state of any remaining empty memory element.

18. The method of claim 17 further comprising:
repeating the setting and reducing in response to a change in the packed data boundary or the amount of quick access memory.

19. A machine readable medium having stored thereon machine executable instructions that, when executed, implement a method comprising:
relocating data items among a plurality of memory elements comprising a physical memory array, to pack said data items into particular ones of the plurality of memory elements;
tracking locations of the data items in the physical memory array with respect to corresponding locations of the data items as defined by an operating system; and
reducing a power state of at least one empty memory element among the plurality of memory elements that contains none of the data items.

20. The machine readable medium of claim 19 wherein relocating the data items comprises:
selecting a particular data item among the plurality of data items;
determining if a packed location is available within the physical memory array for the particular data item; and
moving the particular data item to the packed location if the packed location is available.

21. The machine readable medium of claim 19 wherein tracking the locations of the data items comprises:
recognizing a changed data item in the plurality of data items;
identifying an address location in the physical memory array for the changed data item; and
updating a record for the changed data item based on the address location and the corresponding location of the changed data item as defined by the operating system.

22. The machine readable medium of claim 19 wherein reducing the power state comprises:
identifying a packed data boundary among the plurality of memory elements, said packed data boundary to separate the plurality of memory elements into empty memory elements and occupied memory elements;
determining an amount of quick access memory;
setting enough of the empty memory elements to an active power state to supply the amount of quick access memory; and
reducing the power state of any remaining empty memory element.

23. An apparatus comprising:
relocation logic to relocate data items among a plurality of memory elements comprising a physical memory array, to pack said data items into particular ones of the plurality of memory elements;
tracking logic to track locations of the data items in the physical memory array with respect to corresponding locations of the data items as defined by an operating system; and
power state logic to reduce a power state of at least one empty memory element among the plurality of memory elements that contains none of the data items.

24. The apparatus of claim 23 wherein the relocation logic is further to select a particular data item among the plurality of data items, determine if a packed location is available within the physical memory array for the particular data item, and move the particular data item to the packed location if the packed location is available.

25. The apparatus of claim 23 wherein the tracking logic is further to recognize a changed data item in the plurality of data items, identify an address location in the physical memory array for the changed data item, and update a record for the changed data item based on the address location and the corresponding location of the changed data item as defined by the operating system.

26. The apparatus of claim 23 wherein the power state logic is further to identify a packed data boundary among the plurality of memory elements, said packed data boundary to separate the plurality of memory elements into empty memory elements and occupied memory elements, determine an amount of quick access memory, set enough of the empty memory elements to an active power state to supply the amount of quick access memory, and reduce the power state of any remaining empty memory element.

27. A system comprising:
a notebook computer; and
a memory power manager, said memory power manager including
relocation logic to relocate data items among a plurality of memory elements comprising a physical memory array, to pack said data items into particular ones of the plurality of memory elements,
tracking logic to track locations of the data items in the physical memory array with respect to corresponding locations of the data items as defined by an operating system, and
power state logic to reduce a power state of at least one empty memory element among the plurality of memory elements that contains none of the data items.

28. The system of claim 27 wherein the relocation logic is further to select a particular data item among the plurality of data items, determine if a packed location is available within the physical memory array for the particular data item, and move the particular data item to the packed location if the packed location is available.

29. The system of claim 27 wherein the tracking logic is further to recognize a changed data item in the plurality of data items, identify an address location in the physical memory array for the changed data item, and update a record for the changed data item based on the address location and the corresponding location of the changed data item as defined by the operating system.

30. The system of claim 27 wherein the power state logic is further to identify a packed data boundary among the plurality of memory elements, said packed data boundary to separate the plurality of memory elements into empty memory elements and occupied memory elements, determine an amount of quick access memory, set enough of the empty memory elements to an active power state to supply the amount of quick access memory, and reduce the power state of any remaining empty memory element.
